(19) United States
(12) Patent Application Publication
(10) Pub. No.: US 2024/0077539 A1
(43) Pub. Date: Mar. 7, 2024

(54) BATTERY MONITORING SYSTEM, CONTROLLER, MONITORING DEVICE, NON-TRANSITORY COMPUTER READABLE MEDIUM AND METHOD FOR MONITORING BATTERY

(71) Applicant: DENSO CORPORATION, Kariya-city (JP)

(72) Inventors: Shogo SHIGEMORI, Kariya-city (JP); Tatsuhiro NUMATA, Kariya-city (JP); Tetsuya WATANABE, Kariya-city (JP)

(21) Appl. No.: 18/455,063

(22) Filed: Aug. 24, 2023

(30) Foreign Application Priority Data
Sep. 7, 2022 (JP) 2022-142180

(51) Int. Cl. G01R 31/371; G01R 31/387; H01M 10/42

(52) U.S. Cl. CPC G01R 31/371; G01R 31/387; H01M 10/425; H01M 2010/4271; H01M 2010/4278

(57) ABSTRACT

In a technique for monitoring a state of a battery, battery monitoring information is acquired via wireless communication from monitoring devices that acquire the battery monitoring information from the battery. A predetermined process is executed based on the battery monitoring information. Instructions are transmitted to the monitoring devices via unicast communication and broadcast communication within a communication cycle. The instructions include an instruction transmitted via the unicast communication to each of the monitoring devices about acquisition of the battery monitoring information, and an instruction transmitted via the broadcast communication to the monitoring devices about a timing of acquisition of the battery monitoring information.

### CROSS REFERENCE TO RELATED APPLICATION

This application is based on and incorporates herein by reference Japanese Patent Application No. 2022-142180 filed on Sep. 7, 2022.

### TECHNICAL FIELD

The present disclosure relates to a battery monitoring system, a controller, a monitoring device, a non-transitory computer readable medium and a method for monitoring a battery.

### BACKGROUND

For example, a vehicle such as a hybrid vehicle (HV), a plug-in hybrid vehicle (PHV), or an electric vehicle (EV) has an assembled battery for running the vehicle such as a lithium ion battery. The assembled battery has a configuration in which battery cells are combined, and a configuration in which a monitoring circuit monitors the state of each battery cell has been proposed.

### SUMMARY

According to an aspect of the present disclosure, a battery monitoring system includes monitoring devices configured to acquire battery monitoring information for monitoring a state of a battery, and a controller configured to acquire the battery monitoring information via wireless communication with the monitoring devices and execute a predetermined process based on the battery monitoring information. The controller transmits instructions to the monitoring devices via unicast communication and broadcast communication within a communication cycle. The instructions include an instruction transmitted via the unicast communication to each of the monitoring devices about acquisition of the battery monitoring information, and an instruction transmitted via the broadcast communication to the monitoring devices about a timing of acquisition of the battery monitoring information.

### BRIEF DESCRIPTION OF THE DRAWINGS

The details of one or more embodiments are set forth in the accompanying drawings and the description below. Other features and advantages will be apparent from the description and drawings, and from the claims.

FIG. 1 is a block diagram schematically illustrating a battery monitoring system according to a first embodiment.

FIG. 2 is a perspective view schematically illustrating a structure of a battery pack.

FIG. 3 is a top view schematically illustrating a structure of the battery pack.

FIG. 4 is an electrical configuration diagram of the battery monitoring system.

FIG. 5 is a first communication sequence diagram schematically illustrating a flow of a communication establishment process between a monitoring device and a controller.

FIG. 6 is a second communication sequence diagram schematically illustrating a flow of a communication establishment process between the monitoring device and the controller.

FIG. 7 is a first communication sequence diagram schematically illustrating a flow of a communication process between the monitoring device and the controller.

FIG. 8 is a second communication sequence diagram schematically illustrating a flow of a communication process between the monitoring device and the controller.

FIG. 9 is a flowchart schematically illustrating contents of a process in the controller.

FIG. 10 is a communication sequence diagram schematically illustrating a flow of a process between the controller and multiple monitoring devices.

FIG. 11 is a flowchart schematically illustrating a flow of a communication re-establishment process.

FIG. 12 is a flowchart schematically illustrating contents of a process in a monitoring device according to a second embodiment.

FIG. 13 is a diagram conceptually illustrating a functional configuration of components of a battery monitoring system.

### DETAILED DESCRIPTION

To begin with, examples of relevant techniques will be described. A battery management system (BMS) in which a mounting unit of the monitoring circuit is configured as a satellite type will be described as a comparative example. In this case, the monitoring circuit is mounted on a monitoring device, and the controller communicates with a satellite battery module via a wireless communication unit. The monitoring circuit mounted on the monitoring device acquires the state of each battery cell based on a command from the controller.

The controller transmits an instruction to the monitoring device using different frequency bands multiple times via broadcast communication without acknowledgement. Thereby, the controller transmits a content of battery control including voltage measurement of the assembled battery and timing of the measurement to the monitoring device. The monitoring device sends the measurement result as a response to the controller by single or multiple unicast communications.

In the system of the comparative example, it may take time to transmit a command due to a large number of times of broadcast communication.

In contrast, according to a technique of the present disclosure, number of times of broadcast communication can be reduced.

According to an aspect of the present disclosure, a battery monitoring system includes monitoring devices configured to acquire battery monitoring information for monitoring a state of a battery, and a controller configured to acquire the battery monitoring information via wireless communication with the monitoring devices and execute a predetermined process based on the battery monitoring information. The controller transmits instructions to the monitoring devices via unicast communication and broadcast communication within a communication cycle. The instructions include an instruction transmitted via the unicast communication to each of the monitoring devices about acquisition of the battery monitoring information, and an instruction transmitted via the broadcast communication to the monitoring devices about a timing of acquisition of the battery monitoring information.

Accordingly, the instruction transmitted via the unicast communication about acquisition of the battery monitoring information and the instruction transmitted via the broadcast communication on the timing of acquisition are used in combination. Therefore, the number of times of the broadcast communication can be reduced as much as possible compared to a configuration in which both the instruction about acquisition of the battery monitoring information and the instruction on the timing of acquisition are transmitted via the broadcast communication.

Hereinafter, some embodiments of a battery monitoring system 1 will be described with reference to the drawings. In the embodiments described below, the same or similar components among the embodiments are assigned the same or similar reference numerals, and description thereof may be omitted.

### First Embodiment

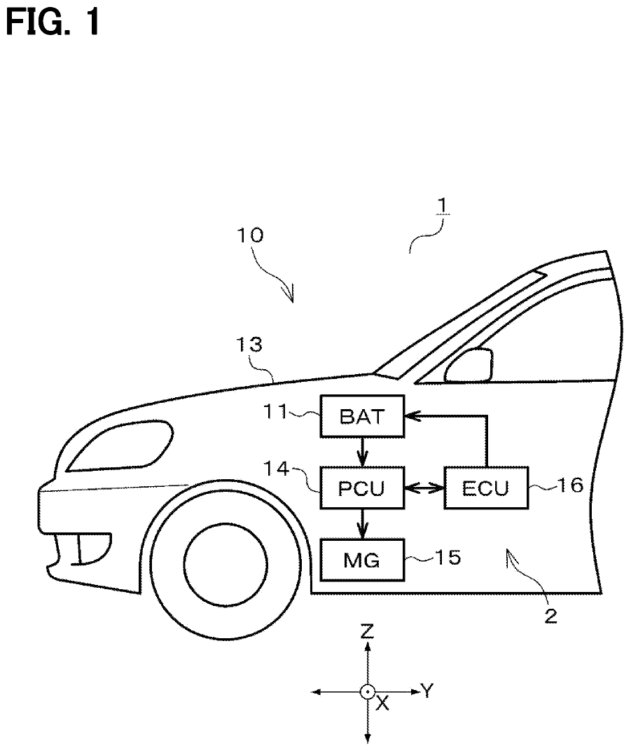

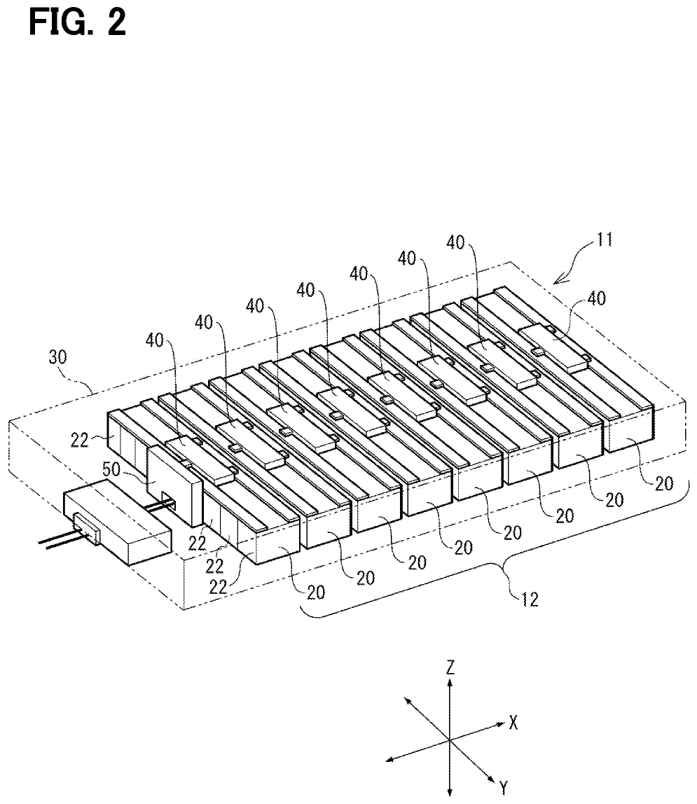

A first embodiment will be described with reference to FIGS. 1 to 11. As shown in FIG. 1, the battery monitoring system 1 mainly includes a battery pack system 2 and is built in a vehicle 10. The vehicle 10 is, for example, a hybrid vehicle (HV), a plug-in hybrid vehicle (PHV), or an electric vehicle (EV). The vehicle 10 uses an assembled battery 12 (see FIG. 2) of a battery pack 11 mounted on the vehicle 10 as at least a part of a drive source for traveling.

The battery pack 11, a power control unit (hereinafter, abbreviated as PCU) 14, a motor 15, and a host ECU 16 are mounted inside a vehicle body 13. The host ECU 16 is configured as an electronic control unit. The battery pack 11 may be disposed in an engine room of the vehicle body 13, but may be disposed under a seat for an occupant such as a driver seat, around a frame of the vehicle body 13, or in a trunk room of the vehicle 10, for example.

As shown in FIG. 2, the battery pack 11 includes battery stacks 20 serving as a battery module, and a large number of battery cells 22 are accommodated in each battery stack 20, thereby forming the assembled battery 12. The assembled battery 12 stores electric power for driving the motor 15 and is used as at least the part of the drive source of the vehicle 10. The PCU 14 illustrated in FIG. 1 supplies the electric power stored in the assembled battery 12 of the battery pack 11 to the motor 15. When the vehicle 10 is braked, the motor 15 returns regenerative electric power to the assembled battery 12, and the assembled battery 12 of the battery pack 11 is charged in accordance with the electric power generated by the motor 15.

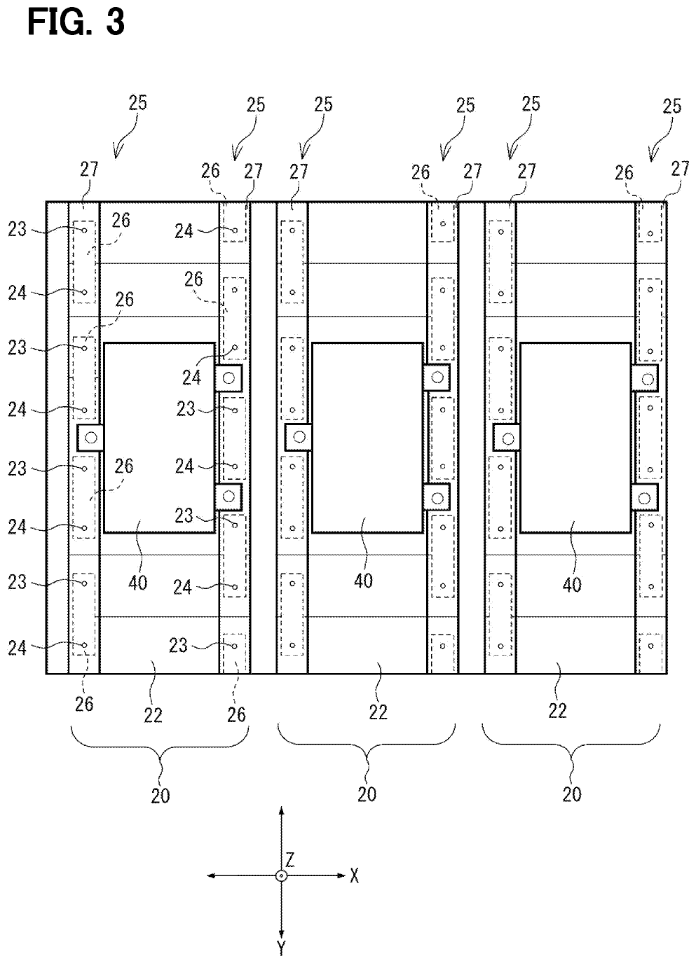

Hereinafter, a structure example of the battery pack 11 will be described with reference to FIGS. 2 and 3. In FIG. 2, a housing 30 is indicated by a two-dot chain line, and the housing 30 is formed in a substantially rectangular parallelepiped shape. The longitudinal direction of the housing 30 is referred to as an X direction, and the lateral direction is referred to as a Y direction. A vertical direction perpendicular to a mounting surface of the housing 30 on the vehicle body 13 is referred to as a Z direction. The X direction, the Y direction, and the Z direction are orthogonal to each other.

As shown in FIG. 2, the assembled battery 12, monitoring devices 40, and a controller 50 are arranged in the housing 30 of the battery pack 11. Each monitoring device 40 includes a monitoring circuit that monitors the battery pack 11, and is referred to as a satellite battery module (SBM). The lower surface of the housing 30 in the Z direction is the mounting surface on the vehicle body 13. In the present embodiment, the X direction is the right-left direction of the vehicle 10, the Y direction is the front-rear direction of the vehicle 10, and the Z direction is the up-down direction of the vehicle 10. The arrangement shown in FIGS. 2 and 3 is only an example. The mounting direction of the battery pack 11 to the vehicle body 13 is an example, and the battery pack 11 may be disposed in any manner with respect to the vehicle 10.

The assembled battery 12 includes the battery stacks 20 arranged side by side in the X direction. The battery stack 20 may be referred to as a battery block, a battery module, or the like. The assembled battery 12 may be formed by connecting the battery stacks 20 in series and/or in parallel, but in the present embodiment, an example in which the battery stacks 20 are connected in series is illustrated.

Each battery stack 20 has battery cells 22. Each of the battery cells 22 is accommodated in a battery case (not shown), whereby the relative positions of the battery cells 22 are fixed. The battery case is made of metal or resin. When the battery case is made of metal and formed in a rectangular box shape, an electrically insulating member is entirely interposed between the wall surface of the battery case and the battery cell 22. The insulating member may be partially interposed between the wall surface of the battery case and the battery cell 22.

The form of the fixing member is not particularly limited as long as the relative positions of the battery cells 22 can be fixed. For example, a configuration in which the battery cells 22 are restrained by a band having a strip shape can be adopted. In this case, a separator for keeping a separation distance between the battery cells 22 may be interposed between the battery cells 22.

Each battery stack 20 includes the battery cells 22 connected in series. In the battery stack 20 of the present embodiment, the battery cells 22 arranged side by side in the Y direction are connected in series. The assembled battery 12 provides a DC voltage source.

Each battery cell 22 is a secondary battery that generates an electromotive force by a chemical reaction. For example, a lithium ion secondary battery, a nickel hydrogen secondary battery, or an organic radical battery can be adopted as the secondary battery. The lithium ion secondary battery is a secondary battery using lithium as a charge carrier. The secondary battery that can be adopted as the battery cell 22 may be not only a secondary battery in which the electrolyte is a liquid but also a so-called all-solid-state battery using a solid electrolyte.

The battery cells 22 are stacked such that lateral surfaces of the battery cases are in contact with each other in the Y direction. Each battery cell 22 has a positive electrode terminal 23 and a negative electrode terminal 24 at different ends in the X direction. The positive electrode terminal 23 and the negative electrode terminal 24 protrude in the Z direction, more specifically, a Z+ direction that is an upward direction. The positions of the end surfaces from which the positive electrode terminal 23 and the negative electrode terminal 24 protrude are the same in the Z direction for each battery cell 22. The battery cells 22 are stacked such that the positive electrode terminals 23 and the negative electrode terminals 24 are alternately arranged in the Y direction.

A pair of linear bus bar units 25 are disposed at both ends of an upper surface of each battery stack 20 in the X direction. The bus bar units 25 are disposed at positions on both ends, in the X direction, of the end surfaces of the battery cases from which the positive electrode terminal 23 and the negative electrode terminal 24 protrude.

Each bus bar unit 25 includes bus bars 26 electrically connecting the positive electrode terminals 23 and the negative electrode terminals 24 alternately arranged in the Y direction, and a bus bar cover 27 covering the bus bars 26. Each bus bar 26 is a plate material made of a metal having superior conductivity such as copper or aluminum. The bus bar 26 electrically connects the positive electrode terminal 23 and the negative electrode terminal 24 of the battery cells 22 adjacent to each other in the Y direction. As a result, in each battery stack 20, the battery cells 22 are connected in series.

Here, an electrical connection state of a certain battery stack 20 will be described. In the certain battery stack 20, one end of a certain first battery cell 22 is a positive electrode, and the other end is a negative electrode. A positive electrode terminal 23 is connected to the positive electrode of the battery cell 22, and a negative electrode terminal 24 is connected to the negative electrode of the battery cell 22. A second battery cell 22 is disposed to face a lateral side of the first battery cell 22 in the Y direction. The second battery cell 22 is opposite to the first battery cell 22 in positions of the positive electrode and the negative electrode in the X direction. The negative electrode terminal 24 of the first battery cell 22 is connected to the positive electrode terminal 23 of the second battery cell 22 by the bus bar 26.

Further, a third battery cell 22 is disposed to face a lateral side of the second battery cell 22 in the Y direction. The third battery cell 22 is opposite to the second battery cell 22 in positions of the positive electrode and the negative electrode in the X direction. The negative electrode terminal 24 of the second battery cell 22 and the positive electrode terminal 23 of the third battery cell 22 are connected by a bus bar 26. As described above, the battery cells 22 are arranged in the Y direction while switching the positions of the positive electrode and the negative electrode in the X direction, and the positive electrode terminal 23 and the negative electrode terminal 24 are connected by the bus bar 26. Accordingly, the battery cells 22 of each battery stack 20 are electrically connected in series.

In each battery stack 20, one of two battery cells 22 located at the opposite ends of the battery cells 22 arranged in the Y direction has the highest potential, and the other has the lowest potential. A predetermined wire is connected to at least one of the positive electrode terminal 23 of the battery cell 22 having the highest potential and the negative electrode terminal 24 of the battery cell 22 having the lowest potential.

As shown in FIGS. 2 and 3, the battery stacks 20 are arranged in the X direction. The positive electrode terminal 23 of the battery cell 22 having the highest potential in one of two battery stacks 20 adjacent to each other in the X direction is connected via a predetermined wire to the negative electrode terminal 24 of the battery cell 22 having the lowest potential in the other of the two battery stacks 20. Accordingly, the battery stacks 20 are electrically connected in series.

Therefore, one of two battery stacks 20 located at the opposite ends of the battery stacks 20 arranged in the X direction becomes a highest potential battery stack 20, and the other becomes a lowest potential battery stack 20. An output terminal is connected to the positive electrode terminal 23 of the battery cell 22 having the highest potential among the battery cells 22 in the highest potential battery stack 20. An output terminal is connected to the negative electrode terminal 24 of the battery cell 22 having the lowest potential among the battery cells 22 in the lowest potential battery stack 20. These two output terminals are connected to an electric device such as the PCU 14 mounted on the vehicle 10. The positive electrode terminal 23 and the negative electrode terminal 24 may at least partially face each other or not face each other at all in the X direction.

Two of the battery stacks 20 adjacent to each other in the X direction may not be electrically connected via a predetermined wire, and any two of the battery stacks 20 may be electrically connected via a predetermined wire.

Each bus bar cover 27 shown in FIG. 3 is formed of an electrically insulating material such as resin. The bus bar cover 27 is provided linearly from one end to the other end of the battery stack 20 along the Y direction such that the bus bar cover 27 cover the multiple bus bars 26. The bus bar cover 27 may have a partition wall. By providing the partition wall, it is possible to enhance insulation between the two bus bars 26 adjacent to each other in the Y direction.

The monitoring devices 40 are provided for the battery stacks 20, respectively. As shown in FIG. 2, a monitoring device 40 is arranged between a pair of bus bar units 25 on each of the battery stacks 20. The monitoring device 40 is arranged to face an end surface of the battery case in the Z direction, and the positive electrode terminal 23 and the negative electrode terminal 24 protrudes from the end surface. The monitoring device 40 and the end surface may be separated from each other in the Z direction or may face each other and be in contact with each other in the Z direction. An object such as an insulating sheet may be interposed between the monitoring device 40 and the end surface.

The monitoring device 40 is fixed to the bus bar units 25 with a screw or the like. As will be described later, the monitoring device 40 is capable of performing wireless communication with the controller 50. An antenna 49, which will be described later, included in the monitoring device 40 is disposed so as not to overlap with the bus bar units 25 in the Z direction, that is, so as to protrude more than the bus bar units 25 in the Z direction.

A coupling member such as a screw that couples the monitoring device 40 and the bus bar units 25 may be made of a non-magnetic material, for example, thereby improving a performance of wireless communication. For components provided in the battery stacks 20, a nonmagnetic material may be used particularly when magnetic properties are not required.

In the present embodiment, the monitoring devices 40 are arranged in the X direction inside the housing 30. The positions of the monitoring devices 40 are the same in the Y direction. According to this arrangement, the arrangement intervals of the monitoring devices 40 can be shortened, and the wireless communication characteristics can be improved.

The monitoring devices 40 are respectively attached to end surfaces of the battery stacks 20 in the Z direction, and the controller 50 is attached to one end surface of all the battery stacks 20 in the X direction.

The antenna 57 of the controller 50 is provided so as to protrude upward in the Z direction more than the bus bar units 25. The antenna 57 connected to the controller 50 is arranged, for example, at the same height in the Z direction as the antenna 49 of the monitoring device 40. The arrangement relationship between the antennas 49 and 57 is not limited to this relationship.

The housing 30 is capable of reflecting electromagnetic waves, for example. EMC stands for Electromagnetic Compatibility. The housing 30 includes a resin material and a metal having magnetic characteristics for reflecting electromagnetic waves, that is, a magnetic material. The housing 30 may include the resin material while the magnetic material covering the resin material or being embedded in the resin material. The housing 30 may include carbon fibers. The housing 30 may include a material having a capability of absorbing electromagnetic waves instead of a capability of reflecting electromagnetic waves.

The housing 30 includes a hole through which an accommodation space accommodating the battery pack 11 communicates with an external space outside the accommodation space. The hole is used for ventilation, energization of power lines and signal lines, for example. When the hole is provided, a covering portion (not shown) may be provided to cover the hole. The cover portion is formed of, for example, a connector, an electromagnetic shielding member, or a sealing material. The cover portion closes a part or all of the hole between the accommodation space of the battery pack 11 and the external space outside the accommodation space.

The covering portion includes, for example, a metal material having magnetic properties. The covering portion may include a resin material while the magnetic material covering the resin material or being embedded in the resin material. The covering portion may include carbon fibers.

The hole of the housing 30 may be covered by an element accommodated in the accommodation space of the housing 30 without providing the covering portion additionally. The power lines and the signal lines may be disposed across the accommodation space and the external space while being held by an electrically insulating member forming a part of a wall of the housing 30.

The attachment structure of the monitoring devices 40 and the controller 50 is not limited to the structure illustrated in FIG. 2. For example, the monitoring devices 40 may be attached to the battery stacks 20 inside the housing 30, respectively, but the controller 50 may be attached to an outer wall surface of the housing 30. For example, an attachment structure in which a wall surface of the housing 30 is provided in a region across which one of the monitoring devices 40 and the controller 50 face each other may be used. In this case, although a propagation environment of radio waves between the monitoring devices 40 and the controller 50 deteriorates as compared with the attachment structure illustrated in FIG. 2, the attachment structure is sufficient to execution of a communication process between the monitoring devices 40 and the controller 50.

In the present embodiment, the battery stacks 20 in each of which the battery cells 22 are packed are prepared as modules and directly stored in the housing 30. However, the present invention may be applied to a so-called module-less structure. For example, as referred to as “cell to pack”, modularization of the battery cells 22 may be omitted, and the battery cells 22 may be directly stored in the battery pack 11. The “cell to pack” may be referred to as CTP.

As referred to as “module to platform”, the battery stacks 20 may be directly mounted on a frame or platform of the vehicle 10. The “module to platform” may be referred to as MTP. As also referred to as “cell to chassis”, the battery cells 22 may be directly packed on a chassis of the vehicle 10 as part of the vehicle body structure. The “cell to chassis” may be referred to as CTC.

As described above, even if the battery pack 11 does not adopt a structure of being housed in the housing 30, diffuse reflection occurs when wireless communication is performed between the controller 50 and the monitoring devices 40. Since the positions of the controller 50 and the monitoring devices 40 are fixed, the controller 50 and the monitoring devices 40 are less likely to be affected by a temporal communication position change such as a communication process in a smartphone or a tablet terminal. However, the controller 50 and the monitoring devices 40 are more likely to be affected by the diffuse reflection between the controller 50 and the monitoring devices 40.

The PCU 14 illustrated in FIG. 1 executes bidirectional power conversion between the battery pack 11 and the motor 15 in accordance with a control signal from the host ECU 16. The PCU 14 includes, for example, an inverter that drives the motor 15, and a converter that boosts a DC voltage supplied to the inverter to be equal to or higher than an output voltage of the battery pack 11.

The motor 15 is an AC rotating electric machine, and is, for example, a three-phase AC synchronous motor in which a permanent magnet is embedded in a rotor. The motor 15 is driven by the PCU 14 to generate a rotational driving force, and the driving force generated by the motor 15 is transmitted to driving wheels of the vehicle 10. On the other hand, during braking of the vehicle 10, the motor 15 operates as a generator and performs regenerative power generation. The electric power generated by the motor 15 is supplied to the battery pack 11 through the PCU 14 and stored in the assembled battery 12 of the battery pack 11.

The host ECU 16 includes a CPU, a ROM, a RAM, a memory such as a nonvolatile semiconductor storage device, and an input/output port for inputting and outputting various signals. A processing program to be executed by the host ECU 16 is stored in the memory, and the CPU executes the program stored in the memory. The memory is used as a non-transitory tangible storage medium. The host ECU 16 receives information of the assembled battery 12 from the controller 50 of the battery pack 11. The information is, for example, a voltage and a state of charge (SOC). Then, the host ECU 16 controls driving of the motor 15 and charging and discharging of the battery pack 11 by controlling the PCU 14.

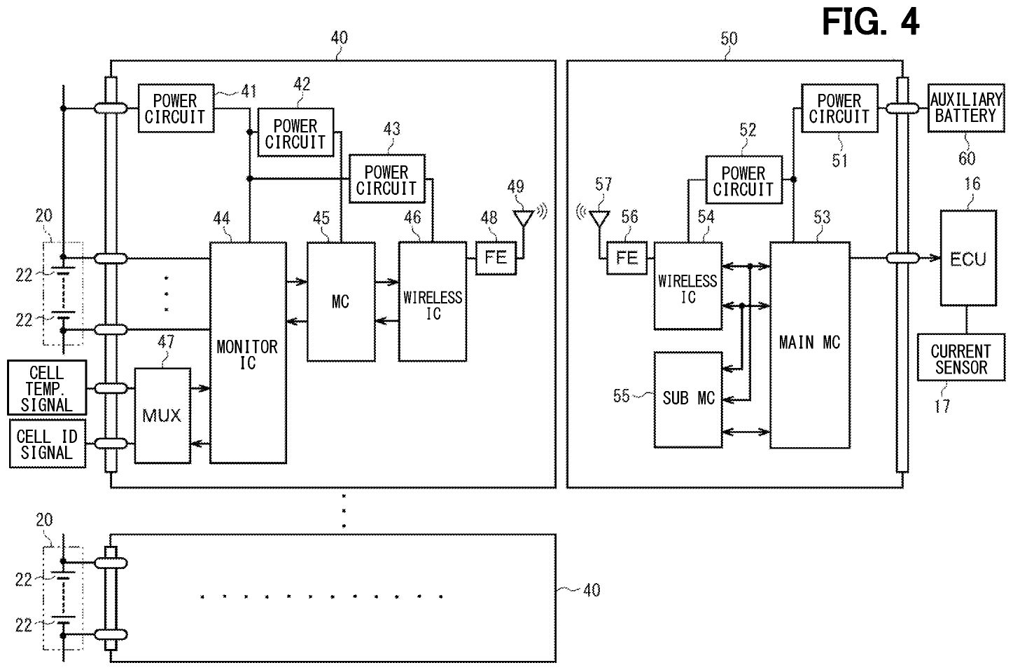

A current sensor 17 shown in FIG. 4 is connected in series to the assembled battery 12 in which the battery cells 22 are connected in series. Accordingly, a current flowing through the entire assembled battery 12 can be measured by the current sensor 17. As shown in FIG. 4, the current sensor 17 is connected to the host ECU 16. The host ECU 16 can acquire information of the current flowing through the assembled battery 12 and the battery cells 22 from sensing information of the current sensor 17.

Although the current sensor 17 is connected to the host ECU 16, the current sensor 17 may be connected to the controller 50, and the controller 50 may acquire information on the current flowing through the assembled battery 12 by the current sensor 17. Since the controller 50 and the host ECU 16 can be communicatively connected to each other, the current information flowing through the assembled battery 12 can be shared with each other regardless of which configuration acquires the information of the current from the current sensor 17.

Hereinafter, specific configurations of the monitoring devices 40 and the controller 50 will be described.

As illustrated in FIG. 4, the monitoring device 40 includes power circuits 41, 42, 43, a monitor IC 44, a microcontroller 45 (MC), a wireless IC 46, a selector circuit 47, a matching circuit 48, and an antenna 49. The power circuit 41 of the monitoring device 40 generates an operation voltage using the voltage supplied from the battery stacks 20, and supplies the generated voltage to the power circuits 42 and 43 and to the monitor IC 44. The power circuit 42 generates an operation voltage using the output of the power circuit 41 and supplies the generated voltage to the microcontroller 45. The power circuit 43 generates an operation voltage using the output of the power circuit 41 and supplies the generated voltage to the wireless IC 46.

The selector circuit 47 of the monitoring device 40 receives an input of sensor signals. The sensor signals include a cell temperature signal indicating a cell temperature of the battery cells 22 measured by a temperature sensor (not shown) mounted on the battery stack 20, and a cell identification signal indicating a type of the battery cells 22, i.e., cell identification information. The selector circuit 47 selects a signal from among the sensor signals, and inputs the selected signal to the monitor IC 44. The monitor IC 44 of the monitoring device 40 senses a cell voltage, the cell temperature and the cell identification information of the battery cells 22, and stores these as battery monitoring information in the memory of the wireless IC 46 through the microcontroller 45. The monitor IC 44 generates malfunction diagnosis information by executing a malfunction diagnosis of the circuit portion of the monitoring device 40, monitors the malfunction diagnosis information, and stores the malfunction diagnosis information in the memory of the wireless IC 46 through the microcontroller 45.

The microcontroller 45 of the monitoring device 40 receives the battery monitoring information or the malfunction diagnosis information input from the monitor IC 44 and transmits the battery monitoring information or the malfunction diagnosis information to the wireless IC 46. The microcontroller 45 represents a control circuit having a function of controlling the battery monitoring information or a schedule of the malfunction diagnosis of the monitor IC 44.

The wireless IC 46 of the monitoring device 40 receives the battery monitoring information or the malfunction diagnosis information from the microcontroller 45 and transmits the information to the controller 50, i.e., a master side. At this time, the wireless IC 46 transmits the information to a wireless IC 54 of the controller 50, i.e., the master side, and receives information from the wireless IC 54 of the controller 50. The wireless IC 46 represents a communication device that controls, for example, a data size, a format, a schedule and error detection in communication between the monitoring device 40 and the controller 50.

The matching circuit 48 and the antenna 49 of the monitoring device 40 represent a physical interface for converting an output signal of the wireless IC 46 into a radio wave and radiating the radio wave to the air, and for receiving the radio wave propagated in the air and inputting the radio wave to the wireless IC 46.

The microcontroller 45 described above may not be provided. In this case, the wireless IC 46 and the monitor IC 44 may directly communicate with each other. The wireless IC 46 of the monitoring device 40 may manage an acquisition schedule or a transmission schedule of the battery monitoring information and the malfunction diagnosis information of the monitor IC 44.

The controller 50 includes power circuits 51 and 52, a main microcontroller 53 (main MC), the wireless IC 54, a sub microcontroller 55 (sub MC), a matching circuit 56, and an antenna 57. The power circuit 51 of the controller 50 generates an operating voltage using a voltage supplied from an auxiliary battery 60, and supplies the operating voltage to the power circuit 52 and the main microcontroller 53. The power circuit 52 generates an operating voltage using the output of the power circuit 51 and supplies the operating voltage to the wireless IC 54.

The matching circuit 56 and the antenna 57 of the controller 50 represent a physical interface for converting a signal output from the wireless IC 54 into a radio wave and radiating the radio wave to the air, and for receiving the radio wave propagated in the air and inputting the radio wave to the wireless IC 54.

The wireless IC 54 of the controller 50 receives the battery monitoring information or the malfunction diagnosis information from the wireless IC 46 of the monitoring device 40, and transmits the information to the main microcontroller 53 of the controller 50. The wireless IC 54 of the controller 50 receives data transmitted from the main microcontroller 53 and transmits the data to the wireless IC 46 of the monitoring device 40. The wireless IC 54 represents a communication device that controls a data size, a format, a schedule, error detection in communication between the monitoring device 40 and the controller 50.

The main microcontroller 53 of the controller 50 uses information such as the voltage and temperature of the battery cells 22 transmitted from the wireless IC 46 to calculate, for example, an SOC and diagnosis information as a state index of the battery cells 22. The main microcontroller 53 transmits the SOC and the diagnosis information to the host ECU 16. The main microcontroller 53 controls switching of an ignition on/off state and equalization control.

The main microcontroller 53 transmits information such as a control signal to the monitoring device 40 through wireless communication via the wireless ICs 46 and 54 to control the operation state of the monitoring device 40. The sub microcontroller 55 of the controller 50 monitors data between the wireless IC 54 and the main microcontroller 53, and monitors an operation state of the main microcontroller 53. The sub microcontroller 55 may monitor the operation state of the wireless IC 54.

In the present embodiment, the controller 50 includes the sub microcontroller 55, and the sub microcontroller 55 monitors data between the wireless IC 54 and the main microcontroller 53, and monitors the operation state of the main microcontroller 53. However, the configuration of the controller 50 is not limited to this example. For example, the controller 50 may not include the sub microcontroller 55.

When the microcontroller 45 is not mounted on the monitoring device 40 as described above, the main microcontroller 53 of the controller 50 may manage the acquisition schedule of the battery monitoring information, the acquisition schedule of the malfunction diagnosis information, or the communication schedule in the monitor IC 44 instead of the microcontroller 45.

In the present embodiment, the main microcontroller 53 of the controller 50 calculates, for example, the SOC and the diagnosis information as the state index of the battery cells 22 using information such as the voltage and the temperature of the battery cells 22 transmitted from the wireless IC 46. Then the main microcontroller 53 transmits the SOC and the diagnosis information to the host ECU 16. However, the calculation of the battery information is not limited to this example.

For example, the microcontroller 45 of the monitoring device 40 may calculate the SOC and the diagnosis information as the state index of the battery cells 22 using the information such as the voltage and the temperature of the battery cells 22 acquired by the monitor IC 44, and then transmit the calculation result to the wireless IC 54 of the controller 50. In other words, the microcontroller 45 of the monitoring device 40 may execute an abnormality diagnosis of the battery cells 22 or the monitor IC 44 using the calculation result, and may transmit the result of the abnormality diagnosis to the wireless IC 54 of the controller 50.

The information such as the voltage and the temperature of the battery cells 22 acquired by the monitor IC 44 of the monitoring device 40 may be calculated by the wireless IC 46 of the monitoring device 40. Furthermore, the information such as the voltage and the temperature of the battery cells 22 acquired by the monitor IC 44 of the monitoring device 40 may be calculated by the wireless IC 54 of the controller 50. In addition, the microcontroller 45 of the monitoring device 40 may execute the abnormality diagnosis of the battery cells 22 using the calculation result, and may transmit the result of the abnormality diagnosis to the wireless IC 54 of the controller 50.

Next, wireless communication between the monitoring device 40 and the controller 50 will be described with reference to FIGS. 4 to 11. In the battery monitoring system 1 according to the present embodiment, the monitoring devices 40 are connected to the controller 50 via a star network in which the controller 50 is a central hub, and packet communication is possible between the monitoring devices 40 and the controller 50. In the battery monitoring system 1, the number of communication nodes is three or more.

The controller 50 individually establishes communication with each of the monitoring devices 40 and wirelessly communicates information. Hereinafter, wireless communication between one controller 50 and one monitoring device 40 will be described, but the controller 50 executes a similar process with all of the monitoring devices 40.

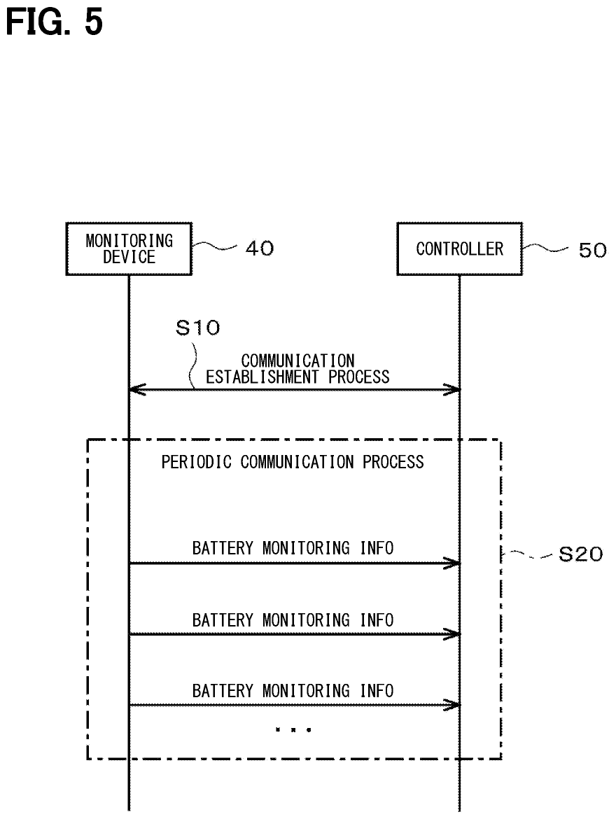

As illustrated in FIG. 5, the monitoring device 40 and the controller 50 execute a communication establishment process in S10. The communication establishment process is executed, for example, when the monitoring device 40 is activated and when the controller 50 is activated. When starting the vehicle 10, a user operates the ignition switch from OFF to ON, and at this time, a start signal is given to the controller 50. When the controller 50 is activated, the communication establishment process is executed between the controller 50 and all the monitoring devices 40. The communication establishment process is a process necessary for unicast communication UC, and is not necessary for broadcast communication BC. When the communication establishment process is succeeded, the controller 50 continues a periodic communication process in step S20 of FIG. 5 with the monitoring device 40 with which communication is established.

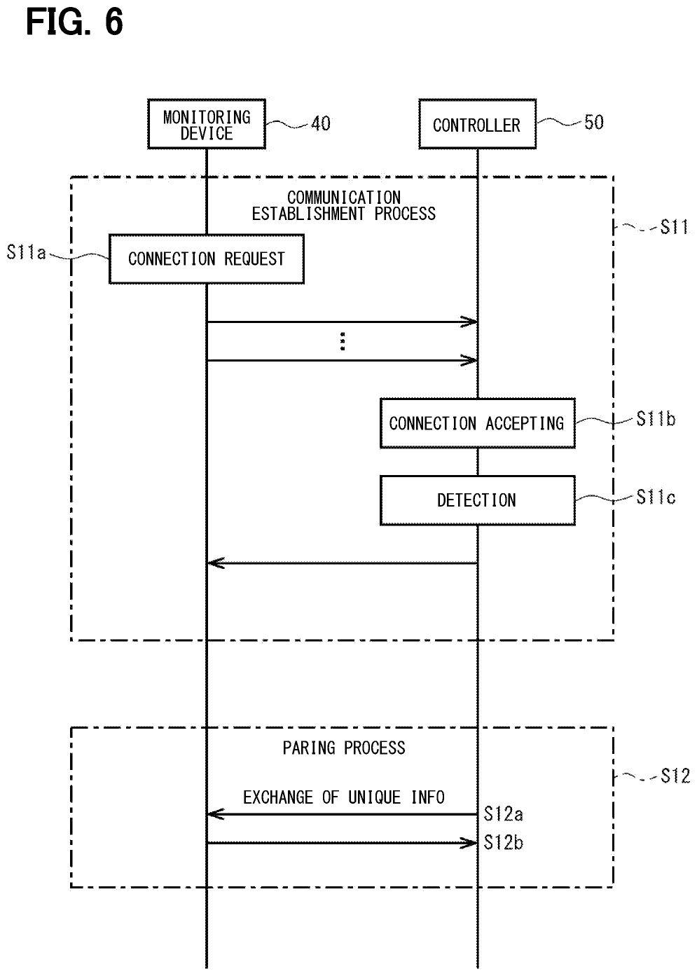

As shown in FIG. 6, the communication establishment process can be divided into a connection establishment process shown in step S11 and a pairing process shown in step S12. The monitoring device 40 and the controller 50 execute the connection establishment process in step S11. The connection establishment process is executed in response to a connection request from the monitoring device 40 in step S11a.

When the monitoring device 40 transmits a connection request packet to the controller 50 in step S11a, the controller 50 receives the connection request packet in step S11b. When the monitoring device 40 executes an advertising operation, the connection request packet is referred to as an advertisement packet. The connection request packet includes, for example, ID information of the monitoring device 40 and ID information of the controller 50. The monitoring device 40 cyclically transmits the connection request packet until connection establishment is completed.

The controller 50 detects the monitoring device 40 by receiving the connection request packet via a connection accepting operation, and then the controller 50 transmits a connection packet as a response to the detected monitoring device 40 in step S11c. When the monitoring device 40 receives the connection packet, the monitoring device 40 can recognize establishment of connection with the controller 50. Accordingly, the target monitoring device 40 can establish a connection with the controller 50. When the connection establishment is completed, the monitoring device 40 stops transmitting the connection request packet.

When the connection establishment process ends, a pairing process is subsequently executed. The pairing process is a process for encrypted data communication, and includes a process of exchanging unique information as illustrated in steps S12a and S12b. In this exchange process, unique information held by each other is exchanged. Encryption using the unique information can be performed after execution of the exchange process in steps S12a and S12b. The unique information is, for example, key information or information for generating a key. Therefore, the communication establishment process shown in step S10 of FIG. 5 ends.

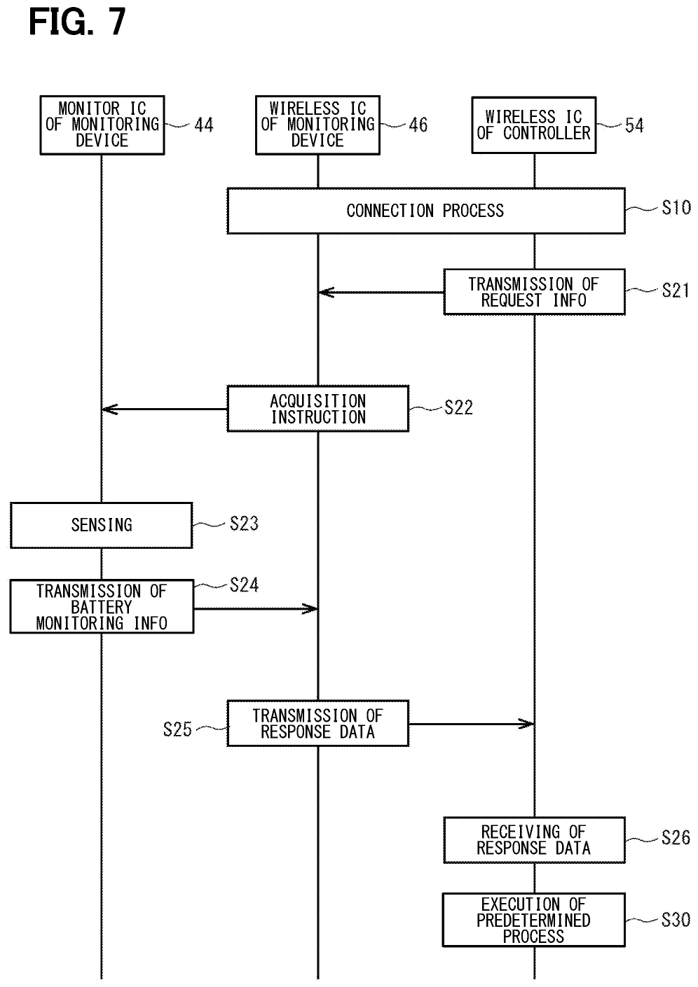

When the communication establishment process of step S10 illustrated in FIG. 5 is completed, the monitoring device 40 and the controller 50 can execute the periodic communication process in step S20 illustrated in FIG. 5. As illustrated in FIG. 7, the controller 50 transmits request information in step S21 to the monitoring device 40 that has completed the connection process with the controller 50. The controller 50 transmits, for example, the request information including a request for acquisition of the battery monitoring information and/or the malfunction diagnosis information of the monitor IC 44 and a request for transmission of the acquired information.

Upon receiving the request information, the wireless IC 46 of the monitoring device 40 transmits, in step S22, an acquisition instruction to the monitor IC 44 to acquire the battery monitoring information. The wireless IC 46 of the present embodiment transmits the acquisition instruction to the monitor IC 44 through the microcontroller 45.

When the monitor IC 44 receives an input of the acquisition instruction, the monitor IC 44 executes a sensing process in step S23. In the sensing process, the monitor IC 44 acquires the temperature of each battery cell 22 as the battery monitoring information together with the cell identification signal through the selector circuit 47. The monitor IC 44 functions as an acquisition unit 40a. The monitor IC 44 executes malfunction diagnosis of its own circuit.

Next, in step S24, the monitor IC 44 transmits the acquired battery monitoring information and the malfunction diagnosis information to the wireless IC 46 via the microcontroller 45. When the microcontroller 45 is absent, the monitor IC 44 transmits the information directly to the wireless IC 46.

When the wireless IC 46 receives the information acquired by the monitor IC 44, the wireless IC 46 generates response data including the battery monitoring information and the malfunction diagnosis information and transmits the response data to the controller 50 in step S25. The controller 50 receives the response data in step S26.

The controller 50 executes a predetermined process based on the received response data in step S30. In step S30, for example, the controller 50 executes the predetermined process based on multiple battery monitoring information acquired within a predetermined period.

For example, the controller 50 of the present embodiment acquires a value of a cell voltage from the multiple battery monitoring information acquired from the monitoring device 40 during the predetermined period, and further acquires a value of a cell current through the current sensor 17 connected in series to a battery cell 22. The controller 50 estimates an internal resistance and an open circuit voltage of the battery cell 22 based on the cell voltage and the cell current.

The controller 50 can calculate a SOH based on the estimated internal resistance. SOH is an abbreviation of States Of Health, and is an index indicating a deterioration state of a battery. The controller 50 can detect an abnormality of the battery cell 22 by comparing the open circuit voltages of the battery cells 22 with each other and determining whether a difference between the open circuit voltages is within a certain range. The “predetermined process” executed by the controller 50 is mainly executed by the main microcontroller 53 in the present embodiment, but may be executed by another configuration in the controller 50, or may be executed by the microcontroller 45 or the wireless IC 46 of the monitoring device 40.

In the present embodiment, the controller 50 estimates the internal resistance and the open circuit voltage of the battery cell 22 based on the cell voltage and the cell current. In the example described above, the controller 50 calculates the SOH based on the estimated internal resistance and the estimated open circuit voltage. However, the estimation of the internal resistance, the estimation of the open circuit voltage, and the calculation of the SOH are not limited to this example. For example, the microcontroller 45 of the monitoring device 40 may execute some or all of the operations of estimating the internal resistance, estimating the open circuit voltage, and calculating the SOH. The wireless IC 46 of the monitoring device 40 may execute some or all of the operations of estimating the internal resistance, estimating the open circuit voltage, and calculating the SOH.

The predetermined process executed by the controller 50 is not limited to the above-described process, and may include a process executed each time the battery monitoring information is acquired. For example, the controller 50 may execute the abnormality diagnosis based on the malfunction diagnosis information every time information is acquired from the monitoring device 40. The abnormality diagnosis may be executed periodically. The controller 50 may transmit the acquired battery monitoring information to the host ECU 16 each time the battery monitoring information is acquired, for example. The controller 50 may collectively transmit information received during the predetermined period to the host ECU 16.

While an example in which the monitoring device 40 acquires battery monitoring information on the basis of the acquisition request from the controller 50 has been described, the present invention is not limited to this example. The monitoring device 40 may autonomously acquire battery monitoring information held by the monitoring device 40 and transmit the battery monitoring information to the controller 50 on the basis of a transmission request from the controller 50. When this sequence is used, the process of step S22 is unnecessary.

In the present embodiment, an example has been described in which the battery monitoring system 1 is capable of executing packet communication via the star network in which the monitoring devices 40 are connected to the controller 50 as a central hub. However, the network topology of the controller 50 and the monitoring devices 40 is not limited to this example.

The controller 50 and the monitoring devices 40 may form a mesh network. The network configuration here employs a configuration in which some of the monitoring devices 40 are grouped and connected by wire to form one network, and this grouped monitoring devices 40 function as one device. The mesh network in this case is configured by a topology in which the controller 50 and multiple groups of the monitoring devices 40 are networked. This network configuration may be applied. The controller 50 and the monitoring devices 40 may be connected via a daisy chain network. At least two or more of the star network, the mesh network, and the daisy chain network may be mixed to configure the network. Although the controller 50 and the monitoring devices 40 constitute a wireless connection network as an example, wired connection networks may be mixed. As described above, the network topology between the controller 50 and the monitoring devices 40 is not particularly limited.

In the present embodiment, when starting the vehicle 10, a user operates the ignition switch from OFF to ON, and at this time, a start signal is given to the controller 50. In this way, an example in which the controller 50 is activated by switching the ignition switch from OFF to ON has been described. That is, when the ignition switch is in the OFF state, the controller 50 is in a sleep state. However, the operation of the controller 50 when the ignition switch is in the OFF state is not limited to this example.

For example, even when the ignition switch is turned off, the controller 50 may be activated. In this case, the controller 50 may maintain the connection establishment with the monitoring devices 40.

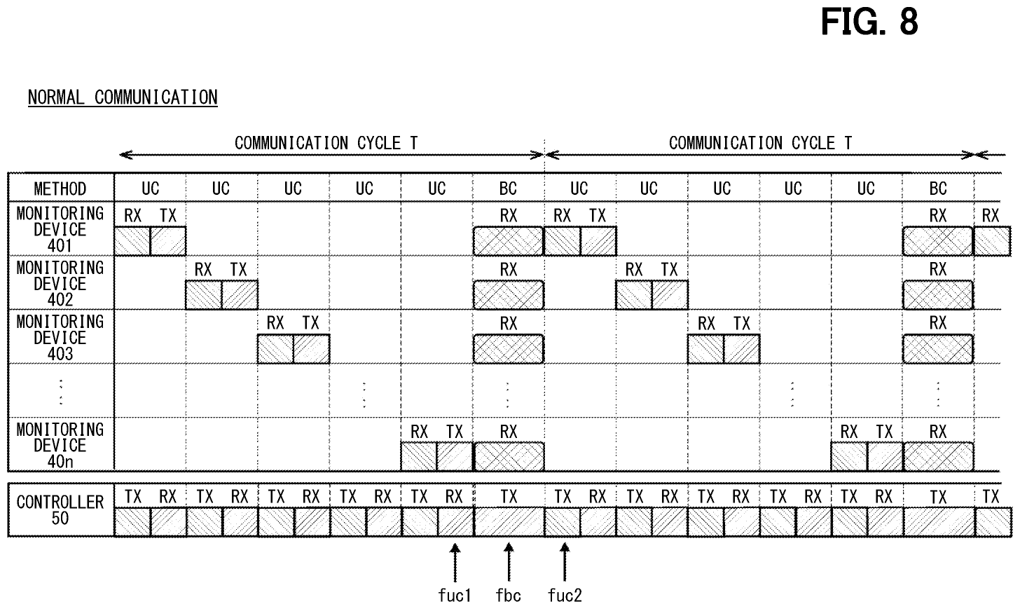

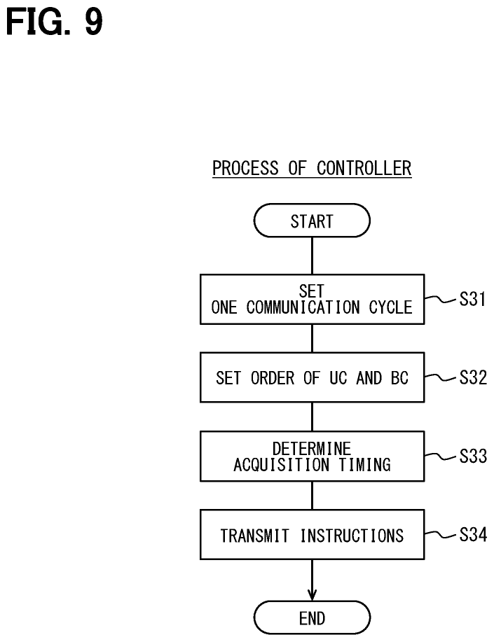

Next, the periodic communication process will be described with reference to FIGS. 8 and 9. When executing the periodic communication process shown in step S20 described above, the controller 50 and the monitoring devices 40 periodically execute the unicast communication UC and the broadcast communication BC. The unicast communication UC indicates a communication method in which the controller 50 designates one monitoring device 40 among the monitoring devices 40 and executes packet data communication. When a monitoring device 40 detects a packet from the network at the time of executing the unicast communication UC, the monitoring device 40 checks the ID information included in the packet. The monitoring device 40 accepts the packet when the packet is associated with the monitoring device 40, and discards the packet when the packet is not associated with the monitoring device 40.

The broadcast communication BC indicates a communication method in which the controller 50 simultaneously transmits data to each monitoring device 40 connected to the network using a broadcast address. In this case, all the monitoring devices 40 detect a packet from the network, check the packet and then accept the packet.

FIG. 8 illustrates time allocation of transmission TX/reception RX in a communication cycle T in which the controller 50 performs wireless communication with n monitoring devices 40 (401, 402, . . . 40n). Hereinafter, when it is necessary to individually describe the monitoring devices 40, the monitoring devices 40 will be described using a reference numerals added with a suffix, such as 401, 402, . . . , 40n. In the present embodiment, as illustrated in FIG. 8, the controller 50 executes the unicast communication UC with each monitoring device 40 and then executes the broadcast communication BC with respect to all the monitoring devices 40, thereby synchronizing the acquisition timing of the cell voltage from each monitoring device 40. Hereinafter, contents of a series of processes including the unicast communication UC and the broadcast communication BC will be described as one communication cycle T.

The process of the controller 50 is illustrated in FIG. 9. The wireless IC 54 of the controller 50 sets the communication cycle T for communication with the monitoring devices 40 in step S31. The setting of the communication cycle T is a function of a cycle setting unit 50a of the controller 50. In an initial state, the controller 50 sets the communication cycle T so that data communication with each of the monitoring devices 40 is executed once. The communication cycle T is set to a total time of a time for the unicast communication UC with the monitoring devices 40 and a time for the broadcast communication BC with all the monitoring devices 40. For example, the communication cycle T is set to a predetermined time of about several tens of milliseconds to several hundreds of milliseconds. For example, the communication cycle T may be stored and managed in advance in a table or the like in a memory mounted on the wireless IC 54 of the controller 50 or the wireless IC 46 of the monitoring device 40, or may be calculated by an arithmetic program using a function.

In step S32, the wireless IC 54 of the controller 50 sets an order of the unicast communication UC with each of the monitoring devices 40 and the broadcast communication BC with the monitoring devices 40 within one communication cycle T, and transmits instructions to the monitoring devices 40 in the set order. From the viewpoint of functional safety, the controller 50 may arrange the order of transmission and reception of communication data and the correspondence relationship.

In the following example, the unicast communication UC is executed and then the broadcast communication BC is executed in the one communication cycle T, but the order may be reversed. In parallel, the main microcontroller 53 of the controller 50 determines the acquisition timing of the battery monitoring information in step S33. The wireless IC 54 of the controller 50, in step S34, transmits instructions to the monitoring devices 40 via the unicast communication UC and the broadcast communication BC in one communication cycle T. The instructions include an instruction transmitted via the unicast communication UC to each of the monitoring devices 40 about acquisition of the battery monitoring information, and an instruction transmitted via the broadcast communication BC to the monitoring devices 40 about timing of the acquisition of the battery monitoring information. The transmission of the instructions is a function of an instruction unit 50b of the controller 50. Here, the controller 50 instructs the monitoring device 40 of the acquisition timing of the battery monitoring information, but the controller 50 may instruct the monitoring device 40 of acquisition of the malfunction diagnosis information.

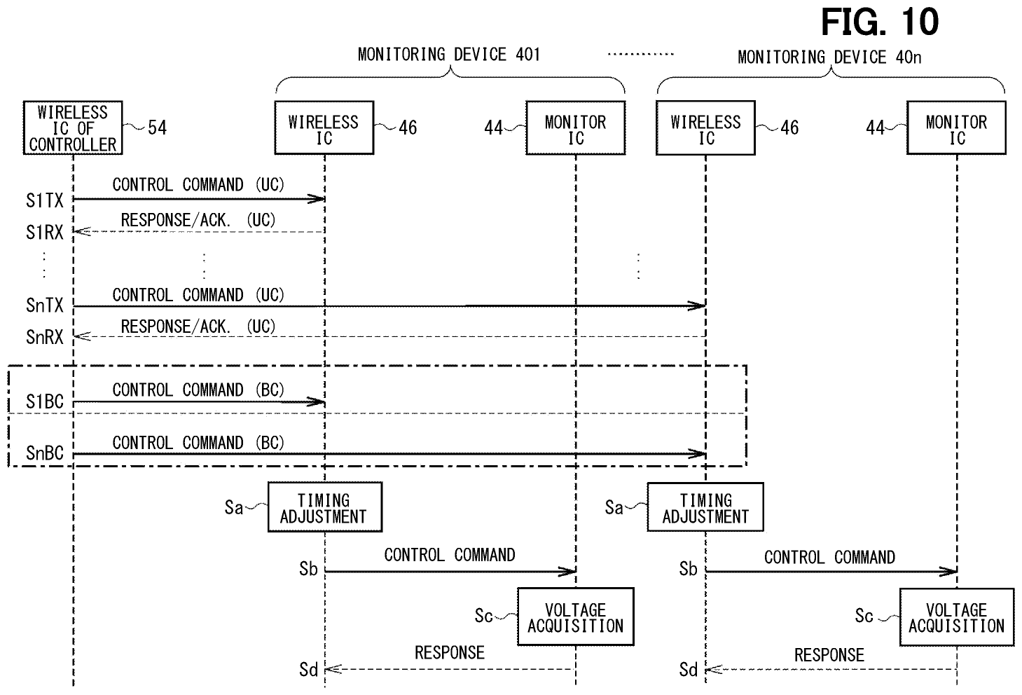

A specific example is shown in FIG. 10. The wireless IC 54 of the controller 50 executes the above-described communication establishment process with the n monitoring devices 401, . . . , 40n, and then transmits a battery monitoring control command via periodic data communication as illustrated in FIG. 10. The wireless IC 54 of the controller 50 transmits the battery monitoring control command including the instructions to each of the monitoring devices 40 via the unicast communication UC in S1TX to SnTX. The battery monitoring control command includes instruction information. The instruction information includes an instruction about acquisition of information such as ID information of the wireless IC 46 of each monitoring device 40, an instruction about acquisition of battery monitoring information such as a cell voltage, an instruction about acquisition of temperature information of the battery cell 22, and an instruction on execution of malfunction diagnosis.

The wireless IC 46 of each monitoring device 401, . . . , 40n transmits an acknowledgement to the controller 50 via the unicast communication UC. The transmission of the acknowledgement is a function of an acknowledgement unit 40b of each of the monitoring devices 40. The monitor IC 44 of the monitoring device 40 has acquired the battery monitoring information such as cell voltage and temperature information based on instructions received in the communication cycle T one cycle or more than one cycles ago, and stores the battery monitoring information in the memory of the microcontroller 45 or the memory of the wireless IC 46. The monitoring devices 401, . . . , 40n transmit the battery monitoring information stored in the memory in advance in addition to the acknowledgement as the response data. The monitoring devices 401, . . . , 40n may transmit the temperature information and the malfunction diagnosis information of the battery cell 22 as long as they are stored in the memory.

Here, the acknowledgement is data that can be received by the wireless IC 54 of the controller 50 to confirm “whether the battery monitoring information transmitted from each monitoring device 401, . . . , 40n is acquired in the latest communication cycle T or acquired in the communication cycle T one cycle or more then one cycles ago” or “which battery monitoring control command is received by each monitoring device 401, . . . , 40n”.

The wireless IC 54 of the controller 50 receives the acknowledgement and receives information included in the response data in S1RX to SnRX. The received information indicates response data corresponding to the instruction content instructed by the wireless IC 54 of the controller 50 one communication cycle or more than one communication cycles ago.

When receiving the acknowledgements from the monitoring devices 40, the wireless IC 54 of the controller 50 confirms an order in which information such as the battery monitoring information is received, and then executes the broadcast communication BC. When the wireless IC 54 receives the acknowledgements from the monitoring devices 40, it can be reliably confirmed that the monitoring devices 40 have received the instructions. The information transmitted from the monitoring devices 40 is the same type of information, but is not necessarily the same.

Thereafter, the wireless IC 54 of the controller 50 transmits the battery monitoring control command including instructions in S1BC to SnBC via the broadcast communication BC. The battery monitoring control command includes instruction information. The instruction information includes an instruction about acquisition timing of battery monitoring information such as cell voltage or temperature information or an instruction about malfunction diagnosis. The controller 50 confirms the acquisition order of the battery monitoring information such as a cell voltage by the monitoring devices 40 and the content of the received information, and then performs the broadcast communication BC.

The controller 50 may simultaneously transmit instructions via broadcasting of a battery monitoring control command to the monitoring devices 401, . . . , 40n to acquire the information at the same time. Here, the battery monitoring control command may be a command for resetting a timer for measuring the transmission/reception timing of communication, and may be a command for instructing the monitoring device 40 to acquire the information at a relative time such as a predetermined time (for example, 5 milliseconds) after the reset command. On the other hand, the battery monitoring control command may instruct the time managed by the timer built in the wireless IC 46 of each monitoring device 401, . . . , 40n to be synchronized with the same time.

Then, even after the instruction of the unicast communication UC, it is possible to minimize the influence of the timer setting error until each monitoring device 40 actually acquires the cell voltage, and it is possible to prevent the acquisition timing of the cell voltage from deviating among the monitoring devices 40. The timings may be set to be different from each other.

As described above, the current sensor 17 that measures the current flowing through the assembled battery 12 is connected to the host ECU 16. The controller 50 may transmit an instruction via the broadcast communication BC to the monitoring devices 40 about acquisition of the voltage of the assembled battery 12 such that the voltage is acquired at the measurement timing of the current flowing through the assembled battery 12. Accordingly, information on the current flowing through the assembled battery 12 and information on the voltage of the battery cell 22 can be acquired in synchronization with each other. Since the power load of the assembled battery 12 varies from moment to moment, it is important to obtain the power consumption during a predetermined period. According to the present embodiment, the current information and the voltage information can be acquired in synchronization with each other, and the power consumption during a certain period can be estimated as accurately as possible.

In the broadcast communication BC, the wireless IC 54 of the controller 50 transmits a packet without ID information of the wireless IC 46 of the monitoring device 40. This is to reduce the transmission/reception error rate due to data corruption or to reduce the internal processing time in the main microcontroller 53 or the wireless IC 54 of the controller 50.

The frequency band used in the broadcast communication BC may be set to a frequency band outside the predetermined frequency band. The above-described predetermined frequency band indicates, for example, a frequency band that is predetermined to be used for each WiFi channel. The controller 50 may measure, for example, the number of communication errors, the number of times of occurrence of retransmission of communication data, and the received signal strength (RSSI) with each of the monitoring devices 40 as communication record information in the installation environment described above. The controller 50 may narrow down a frequency band having a good communication record in advance based on this communication record information, store the narrowed frequency band in an internal memory of the wireless IC 54, and select a frequency band from the frequency bands stored in the memory to execute communication. RSSI is an abbreviation for Received Signal Strength Indicator.

In addition, an external communication unit such as a data communication module (DCM) may be separately mounted on the vehicle 10, and the data communication module may be configured to perform data communication with the outside. DCM is an abbreviation for Data Communication Module. In this case of the vehicle 10, the broadcast communication BC using a frequency band different from the frequency band used in the data communication module may be executed.

As illustrated in FIG. 8, the use frequency band fbc of the broadcast communication BC may be set by excluding the frequency bands fuc1 and fuc2 used in the unicast communications UC that are executed immediately before and after the broadcast communication BC. This is to eliminate influence of the residual reflected wave as much as possible. In the example of FIG. 8, the frequency bands fuc1, fbc, and fuc2 may be set to different bands, or the frequency bands fuc1 and fuc2 may include the same region and be set to be different in region from the frequency band fbc.

The frequency bands fuc1 and fuc2 used in the unicast communications UC before and after the broadcast communication BC are different from the frequency band fbc used in the broadcast communication BC. However, the frequency band fbc used in the broadcast communication BC may be different only from the frequency band (e.g., frequency band fuc1) used in the previous communication (e.g., unicast communication UC), and may include the same band as the frequency band (e.g., frequency band fuc2) used in the subsequent communication (e.g., unicast communication UC).

With such a configuration, the influence of the residual reflected wave in the broadcast communication BC without acknowledgement can be reduced. Therefore, the communication success rate of the broadcast communication BC can be improved. Since a real-time property, i.e., degree of freshness of the battery monitoring information is important for the safety of the vehicle, in the present embodiment, the acquisition timing of the battery monitoring information is suitably synchronized by the broadcast communication BC.

The frequency band fbc used in the broadcast communication BC may be different only from the frequency band (e.g., frequency band fuc2) used in the subsequent communication (e.g., unicast communication UC), and may include the same band as the frequency band (e.g., frequency band fuc1) used in the previous communication (e.g., unicast communication UC). Since the frequency band fbc used in the broadcast communication BC is different from the frequency band used in the subsequent communication (e.g., unicast communication UC), even if a delay occurs in the communication cycle due to a communication malfunction, an operation clock error, or the like, interference with the subsequent communication can be avoided.

In addition, for example, when the order of the broadcast communication BC and the unicast communication UC is set for each communication cycle T, the broadcast communication BC may be continuously executed multiple times without interposing the unicast communication UC in two adjacent communication cycles T. Also in this case, the frequency bands used in the previous or subsequent broadcast communication BC may be different from each other.

Upon receiving a command via the broadcast communication BC, the wireless IC 46 of each monitoring device 401, . . . , 40n reads the instruction information of the controller 50 in Sa of FIG. 10 and adjusts the acquisition timing by the built-in timer. When the wireless IC 46 determines that the acquisition timing has elapsed, the wireless IC 46 transmits a battery monitoring control command to the monitor IC 44 in Sb. When the monitor IC 44 receives the battery monitoring control command, the monitor IC 44 executes the battery monitoring control in Sc to acquire the cell voltage. In Sd, the monitor IC 44 transmits the battery monitoring information including the cell voltage to the wireless IC 54 of the controller 50 as a response.

For example, if the monitor IC 44 includes a timer, the wireless IC 46 may transmit the battery monitoring control command to the monitor IC 44 immediately after receiving the instruction information from the wireless IC 54, and the monitor IC 44 may adjust the acquisition timing in Sa.

When the wireless IC 46 of the monitoring device 40 receives the battery monitoring information from the monitor IC 44, the wireless IC 46 of the monitoring device 40 transmits the battery monitoring information to the wireless IC 54 of the controller 50. The packet transmission is executed at the timing of execution of the unicast communication UC in a communication cycle T subsequent to the end of the broadcast communication BC executed in a previous communication cycle T. In this way, the communication process is repeated for each communication cycle T.

A process at the time of interruption of established communication will be described. When the ignition switch is turned off by the user, the input of the activation signal to the controller 50 is stopped. Then, the controller 50 disconnects the wireless communication.

In addition, for example, depending on an arrangement environment of the battery pack 11 and a mounting environment of the monitoring devices 40 and the controller 50 relative to the housing 30, diffuse reflection of radio waves used for mutual communication between the monitoring devices 40 and the controller 50 may occur.

For example, when the battery pack 11 for a vehicle is accommodated in the flat housing 30 as shown in FIG. 2 or is exposed to a severe environment in response to a demand for a reduction in height in recent years, a propagation space for radio waves cannot be sufficiently secured in a specific direction such as the Z direction in FIG. 2, for example, and the radio waves repeat diffuse reflection inside the housing 30. In this case, the established communication between the controller 50 and the monitoring devices 40 may be interrupted due to deterioration of the communication environment.

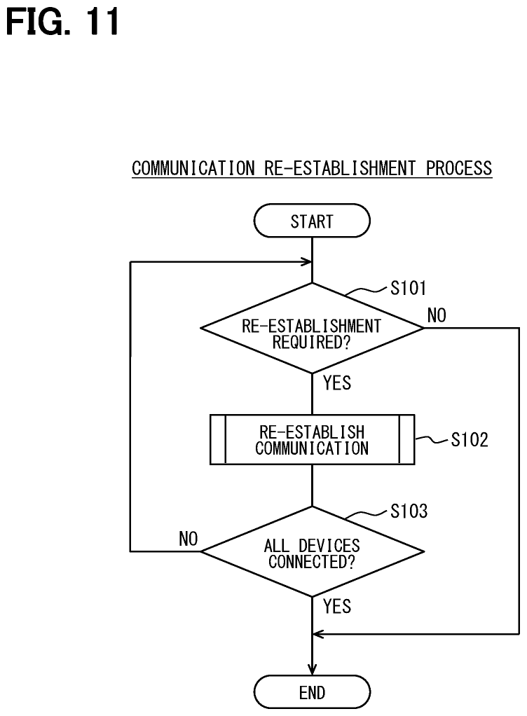

If the established communication between the controller 50 and a certain monitoring device 40 is interrupted, the controller 50 attempts a communication re-establishment process illustrated in FIG. 11 with the monitoring device 40 while the controller 50 maintains the established communication with the other monitoring devices 40.

The controller 50 executes the communication re-establishment process when the established communication with, for example, a monitoring device 401 which is one of all the monitoring devices 40 is interrupted. When the established communication between the controller 50 and the monitoring device 40 is interrupted, the controller 50 executes the communication re-establishment process illustrated in FIG. 11 periodically or when a predetermined condition is satisfied. For example, failure of acquisition of the battery monitoring information from the monitoring device 40 may be used as a trigger to execute the communication re-establishment process.

In step S101, the controller 50 determines whether there is a monitoring device 40 that requires re-establishment of communication with the controller 50. When the controller 50 executes data communication with all the monitoring devices 40, the controller 50 determines that there is no monitoring device 40 that needs communication, and ends the communication re-establishment process. For example, when communication with some of the monitoring devices 40 is disconnected, the controller 50 determines that there is a monitoring device 40 that needs to be reconnected to the controller 50.

The controller 50 may determine whether there is the monitoring device 40 that needs to be reconnected to the controller 50, for example, based on the acquired battery monitoring information. More specifically, when the battery monitoring information such as the cell voltage cannot be acquired a predetermined number of times or for a predetermined time period, the controller 50 determines that the re-establishment of communication is required. The controller 50 may determine whether there is the monitoring device 40 that requires reconnection based on communication record information such as the number of communication errors, the number of data retransmissions, and received signal strength (RSSI).

Alternatively, multiple monitoring devices 40 may determine communication record information such as the number of communication errors, the number of data retransmissions, and the received signal strength, and transmit the communication record information to the controller 50. Then, the controller 50 may determine there is the monitoring device 40 that needs to be reconnected by determining the communication record information included in the response data transmitted from the multiple monitoring devices 40.

When it is determined in step S101 that there is a monitoring device 40 that requires communication re-establishment, the controller 50 re-establishes communication in step S102. The communication re-establishment process shown in step S102 is the same as the communication establishment process shown in step S10 of FIG. 5. The controller 50 executes the communication establishment process with the monitoring device 40 through the connection establishment process in step S11 and the pairing process in step S12.

In step S103 of FIG. 11, the controller 50 determines whether the communication connection with all the monitoring devices 40 at the time of the normal communication is established, and ends the communication re-establishment process when the communication connection with all the monitoring devices 40 is completed. Conversely, when communication connection with all the monitoring devices 40 has not been established, the process returns to step S101, and it is determined whether there is a monitoring device that needs to be reconnected. When it is determined in step S101 that there is another monitoring device 40 that needs to be reconnected, the communication establishment process with the other monitoring device 40 is executed. Accordingly, the controller 50 can continue to establish communication with all the monitoring devices 40.

Hereinafter, a comparative example with respect to the present embodiment will be described. When the controller 50 executes the broadcast communication BC with the multiple monitoring devices 40 multiple times in one communication cycle T, it is likely to take time to transmit a command. In this case, the communication cycle T for acquiring the battery monitoring information may not satisfy a strict cycle requirement required from the system. For example, in a case where a standby time of about several hundred microseconds to several tens of milliseconds is provided between communications, if it is assumed that communication management data necessary for communication is several tens to several hundreds of bytes and a communication speed is 500 KHz, several milliseconds is required for the standby time even in the case of the fastest communication. For example, in a case where the communication cycle T for acquiring the battery monitoring information from the system is set to about several to several tens of milliseconds, the cycle requirement cannot be satisfied because the standby time occupies a considerable time ratio.

Furthermore, even if the controller 50 transmits a command via the broadcast communication BC to the monitoring device 40 multiple times without acknowledgement, not all the monitoring devices 40 can reliably receive the command via the broadcast communication BC. This means that acquisition of the battery monitoring information on all the battery cells 22 cannot be guaranteed, and the original monitoring purpose of the monitoring devices 40 cannot be achieved. In order to increase the reliability of communication, it is necessary to increase the number of retransmissions of the broadcast communication BC. However, if the number of retransmissions is increased, it is difficult to further satisfy the above-described cycle requirement. Further, the broadcast communication BC is usually not encrypted, and there is a possibility of a malicious attack from the outside or a eavesdropping attack. Therefore, it is not preferable to transmit all instructions via the broadcast communication BC.

According to the present embodiment, the instructions are transmitted to the monitoring devices 40 (401, . . . , 40n) via the unicast communication UC and the broadcast communication BC in one communication cycle T. The instructions include an instruction transmitted via the unicast communication UC to each of the monitoring devices 40 about acquisition of the battery monitoring information, and an instruction transmitted via the broadcast communication BC to each of the monitoring devices 40 about timing of acquisition of the battery monitoring information. The unicast communication UC with acknowledgement and the broadcast communication BC without acknowledgement are used in combination.

Therefore, it is possible to ensure acquisition of the battery monitoring information related to the assembled battery 12 while satisfying the required cycle requirement while reducing the number of times of the broadcast communication BC as much as possible. As a result, it is possible to increase the reliability in acquisition of information such as battery monitoring information. Since the number of times of executing the broadcast communication BC in one communication cycle T is reduced as much as possible to, for example, one time, it is possible to increase the safety of communication.

The controller 50 executes the unicast communication UC and the broadcast communication BC for each monitoring device 40, and at this time, the controller 50 can transmit the instruction on the acquisition timing of the battery monitoring information. Therefore, it is possible to minimize difference of the acquisition timing of the battery monitoring information among the monitoring devices 40. As a result, the battery monitoring information can be acquired under the same environmental condition, and it becomes easy to accurately estimate various characteristics during a certain period.

### Second Embodiment

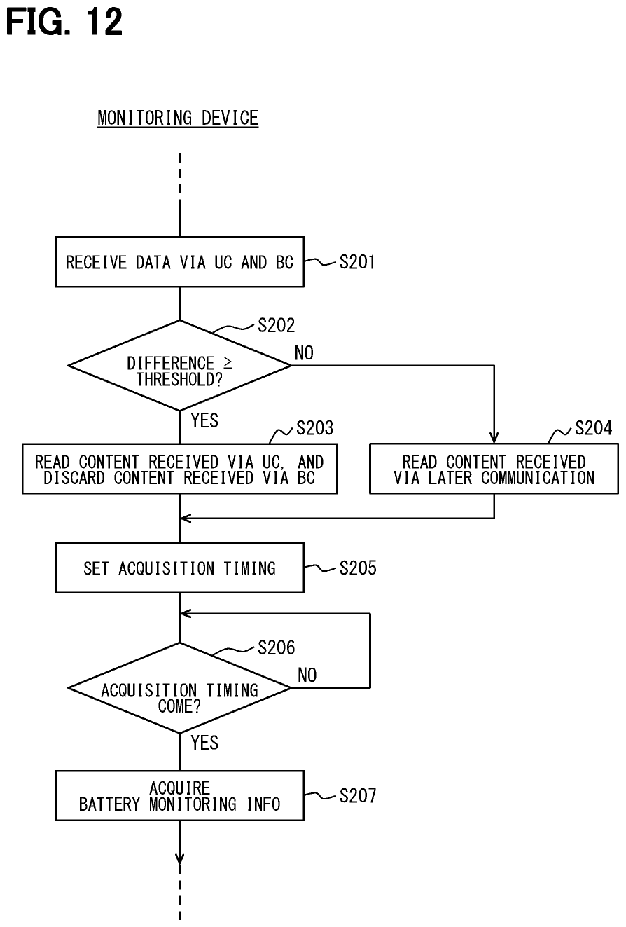

A second embodiment will be described with reference to FIG. 12. In the first embodiment, the controller 50 executes the broadcast communication BC after executing the unicast communication UC, and acquires the battery monitoring information at a battery monitoring control timing that has been instructed via the broadcast communication BC. In the present embodiment, an alternative method of setting the acquisition timing of the battery monitoring information will be described.

The controller 50 may transmit instruction on the battery monitoring control timing via the unicast communication UC. Here, the battery monitoring control timing may be defined by using a relative time such as a predetermined time period (e.g., 5 milliseconds) after the transmission timing of the unicast communication UC as a starting point, or the controller 50 may define the battery monitoring control timing as an absolute time by using a time managed by the timer built in the wireless IC 46 of each monitoring device 401, . . . , 40n.

In the first embodiment, the broadcast communication BC is executed after execution of the unicast communication UC. However, conversely, the unicast communication UC may be executed after execution of the broadcast communication BC.

FIG. 12 illustrates processing contents of the monitoring device 40 when the monitoring device 40 receives an instruction from the controller 50. The wireless IC 54 of the controller 50 transmits the battery monitoring control command to the monitoring device 40 one time for each of the unicast communication UC and the broadcast communication BC in one communication cycle T. The wireless IC 46 of the monitoring device 40 receives communication data, i.e., the battery monitoring control command, via the unicast communication UC and the broadcast communication BC in step S201. During step S201, the wireless IC 46 resets the timer and starts counting at a timing of receiving the communication data via an earlier communication (e.g., unicast communication UC), and measures the time until a timing of receiving the communication data via a later communication (e.g., broadcast communication BC).

In step S202, the wireless IC 46 of the monitoring device 40 determines whether a difference between the receiving timing of the instruction via the broadcast communication BC and the receiving timing of the instruction via the unicast communication UC is greater than or equal to a predetermined threshold.

When the difference is equal to or greater than the predetermined threshold, a communication quality of the broadcast communication BC may be poor, and the communication data transmitted via the broadcast communication BC may not be reliable. On the other hand, the unicast communication UC is encrypted, and an instruction can be appropriately transmitted from the controller 50 to the monitoring device 40. Therefore, when it is determined in step S202 that the difference is equal to or greater than the predetermined threshold, the monitoring device 40 reliably reads the instruction transmitted via the unicast communication UC in step S203, and discards the instruction included in a content received via the broadcast communication BC. Then, the monitoring device 40 sets the acquisition timing of the battery monitoring information in step S205 based on the instruction transmitted via the unicast communication UC. the monitoring device 40 determines YES in step S206 when the acquisition timing comes, and then acquires the battery monitoring information in step S207.

On the other hand, the wireless IC 46 of the monitoring device 40 determines that the wireless communication quality is good when it is determined in step S202 that the difference is not equal to or greater than the predetermined threshold. In this case, it can be estimated that both the unicast communication UC and the broadcast communication BC have high reliability. Since the monitoring device 40 acquires the battery monitoring information after receiving data via these communications, it is easier to accurately synchronize the monitoring devices 40 by acquiring the battery monitoring information immediately after receiving the communication data. Therefore, the wireless IC 46 of the monitoring device 40 may read the content of data received via the later communication in one communication cycle T in step S204, and set the acquisition timing of the battery monitoring information in step S205.

For example, in a case where the unicast communication UC and the broadcast communication BC are executed in this order in one communication cycle T, the wireless IC 54 of the controller 50 transmits the instruction including the acquisition timing of the battery monitoring information via both the unicast communication UC and the broadcast communication BC. The wireless IC 46 of the monitoring device 40 determines whether the difference between the reception timings via the unicast communication UC and the broadcast communication BC is greater than or equal to the predetermined threshold, and confirms the acquisition timing of the battery monitoring information based on this determination result. Accordingly, it is possible to synchronize the acquisition timings of the battery monitoring information by the monitor ICs 44 of the monitoring devices 40.

Conversely, also in a case where the broadcast communication BC and the unicast communication UC are executed in this order in one communication cycle T, the wireless IC 54 of the controller 50 transmits the instruction including the acquisition timing of the battery monitoring information via both the unicast communication UC and the broadcast communication BC. Then, the wireless IC 46 of the monitoring device 40 reads at least the acquisition timing of the battery monitoring information included in data received via the unicast communication UC that is the later communication. Thereby, it is possible to easily synchronize the acquisition timings of the battery monitoring information by the monitor ICs 44 of the monitoring devices 40.

According to the present embodiment, since the monitoring device 40 reads the content received via the later communication and sets the acquisition timing of the battery monitoring information in one communication cycle T, the acquisition timings of the battery monitoring information can be easily synchronized among the monitoring devices 40. Accordingly, the battery monitoring information can be acquired under the same environmental condition, and various characteristics can be easily estimated accurately.

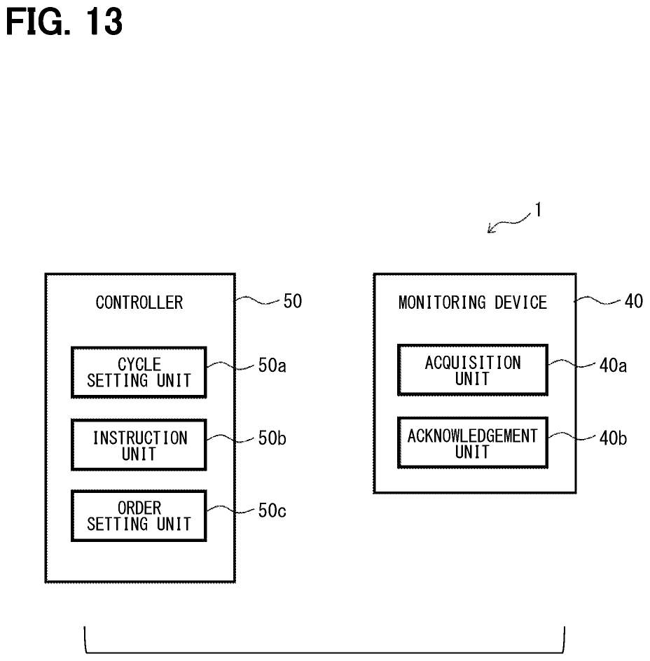

Finally, characteristic functions of the controller 50 and the monitoring devices 40 shown in the first or second embodiment will be summarized with reference to FIG. 13. The controller 50 has a function as the cycle setting unit 50a that sets a communication cycle T of communication with the monitoring devices 40.

The controller 50 has a function as the instruction unit 50b that transmits instructions to the monitoring devices 40 via the unicast communication UC and the broadcast communication BC in one communication cycle T. The instructions include an instruction transmitted via the unicast communication UC to each of the monitoring devices 40 about acquisition of the battery monitoring information, and an instruction transmitted via the broadcast communication BC to the monitoring devices 40 about timing of the acquisition of the battery monitoring information. The controller 50 has a function as an order setting unit 50c that sets the order of the unicast communication UC with each of the monitoring devices 40 and the broadcast communication BC with the monitoring devices 40 in one communication cycle T.

The monitoring device 40 has a function as the acquisition unit 40a that sets the acquisition timing of the battery monitoring information based on acquisition timing transmitted via later communication among the unicast communication UC and the broadcast communication BC in the communication cycle T and acquires the battery monitoring information. The monitoring device 40 has a function as the acknowledgement unit 40b that, after receiving the instruction from the controller 50 about acquisition of the battery monitoring information, transmits the battery monitoring information and the acknowledgement to the controller 50 via the unicast communication UC in response to the instruction. Note that these characteristic functions are merely examples, and the controller 50 or each of the monitoring devices 40 includes various other functions as described in the above-described embodiment.

The present disclosure is not limited to the embodiments described above, and, for example, may be modified or extended, which will be described. The controller 50 may transmit the communication data including an instruction on the battery monitoring control timing along with the ID information of each monitoring device 40 via the broadcast communication BC. Even when the broadcast communication BC is used, the battery monitoring control timing of each monitoring device 40 can be individually determined. Although the battery monitoring system 1 has been described as being configured to include the controller 50 and the monitoring devices 40, the battery monitoring system 1 can also be applied to a configuration in which the functions of the controller 50 is included in the host ECU 16.

The controller 50, the monitoring devices 40, the host ECU 16 and the technique according to the present disclosure may be achieved by a dedicated computer provided by constituting a processor and a memory programmed to execute one or more functions embodied by a computer program. Alternatively, the controller 50, the monitoring devices 40, the host ECU 16 and the technique according to the present disclosure may be achieved by a dedicated computer provided by constituting a processor with one or more dedicated hardware logic circuits.

Alternatively, the controller 50, the monitoring devices 40, the host ECU 16 and the technique according to the present disclosure may be achieved using one or more dedicated computers constituted by a combination of the processor and the memory programmed to execute one or more functions and the processor with one or more hardware logic circuits. A computer program may be stored in a computer-readable non-transitory tangible storage medium as an instruction executed by the computers.

Although the present disclosure has been described in accordance with embodiments, it is understood that the present disclosure is not limited to the embodiments and the structures. The present disclosure encompasses various modifications and variations within the scope of equivalents. In addition, various combinations and modes, and other combinations and modes including only one element, more elements, or less elements are also within the scope and idea of the present disclosure.

What is claimed is:

1. A battery monitoring system comprising:
monitoring devices including processors configured to acquire battery monitoring information for monitoring a state of a battery; and
a controller including a processor configured to acquire the battery monitoring information via wireless communication with the monitoring devices and execute a predetermined process based on the battery monitoring information, wherein
the processor of the controller is further configured to transmit instructions to the monitoring devices via unicast communication and broadcast communication within a communication cycle, and
the instructions include an instruction transmitted via the unicast communication to each of the monitoring devices about acquisition of the battery monitoring information, and an instruction transmitted via the broadcast communication to the monitoring devices about a timing of acquisition of the battery monitoring information.

2. The battery monitoring system according to claim 1, wherein
the processor of the controller is further configured to
set an order of the unicast communication with each of the monitoring devices and the broadcast communication with the monitoring devices in the communication cycle,
transmit the instructions to the monitoring devices in the order, and
transmit an instruction about a timing of acquisition of the battery monitoring information to the monitoring devices via the unicast communication.

3. The battery monitoring system according to claim 2, wherein
the processors of the monitoring devices are further configured to
set a timing of acquisition of the battery monitoring information based on the timing of acquisition transmitted via communication that is later in timing of receiving the instruction among the unicast communication and the broadcast communication in the communication cycle, and
acquire the battery monitoring information at the set timing of acquisition.

4. The battery monitoring system according to claim 2, wherein
the processors of the monitoring devices are further configured to acquire the battery monitoring information based on a content received via the unicast communication when a difference between a timing of receiving the battery monitoring information via the unicast communication and a timing of receiving the battery monitoring information via the broadcast communication is greater than or equal to a predetermined threshold.

5. The battery monitoring system according to claim 1, wherein
the processors of the monitoring devices are further configured to, after receiving the instruction from the controller about acquisition of the battery monitoring information, transmit the battery monitoring information and acknowledgements to the controller via the unicast communication in response to the instruction.

6. The battery monitoring system according to claim 5, wherein
the processor of the controller is further configured to confirm an order of receiving the battery monitoring information and execute the broadcast communication when the controller receives the acknowledgements from the monitoring devices.

7. The battery monitoring system according to claim 1, wherein
the broadcast communication uses a frequency band outside a predetermined frequency band.

8. The battery monitoring system according to claim 1, wherein
the broadcast communication uses a frequency band different from a frequency band used in communication executed before or after the broadcast communication.

9. The battery monitoring system according to claim 1, wherein
the processor of the controller is further configured to
acquire a voltage of the battery as the battery monitoring information from the monitoring devices,
obtain current information from a current sensor configured to measure a current flowing through the battery, and
transmit an instruction via the broadcast communication to the monitoring devices about acquisition of the voltage of the battery such that the voltage is acquired at a measurement timing of the current.

10. A controller for monitoring a state of a battery, the controller comprising:
a processor configured to
acquire battery monitoring information via wireless communication from monitoring devices configured to acquire the battery monitoring information from the battery,
execute a predetermined process based on the battery monitoring information, and
transmit instructions to the monitoring devices via unicast communication and broadcast communication within a communication cycle, wherein
the instructions include an instruction transmitted via the unicast communication to each of the monitoring devices about acquisition of the battery monitoring information, and an instruction transmitted via the broadcast communication to the monitoring devices about a timing of acquisition of the battery monitoring information.

11. The controller according to claim 10, wherein
the processor is further configured to
set an order of the unicast communication with each of the monitoring devices and the broadcast communication with the monitoring devices in the communication cycle,
transmit the instructions to the monitoring devices in the order, and
transmit an instruction about a timing of acquisition of the battery monitoring information to the monitoring devices via the unicast communication.

12. The controller according to claim 11, wherein
the processor is further configured to
receive acknowledgements from the monitoring devices in response to the instructions transmitted to the monitoring devices, and
confirm an order of the monitoring devices receiving the battery monitoring information and execute the broadcast communication when the controller receives the acknowledgements from the monitoring devices.

13. The controller according to claim 10, wherein
the broadcast communication uses a frequency band outside a predetermined frequency band.

14. The controller according to claim 10, wherein
the broadcast communication uses a frequency band different from a frequency band used in communication executed before or after the broadcast communication.

15. The controller according to claim 10, wherein
the processor is further configured to
acquire a voltage of the battery as the battery monitoring information from the monitoring devices,
obtain current information from a current sensor configured to measure a current flowing through the battery, and
transmit an instruction via the broadcast communication to the monitoring devices about acquisition of the voltage of the battery such that the voltage is acquired at a measurement timing of the current.

16. A monitoring device for monitoring a state of a battery, the monitoring device comprising:
a processor configured to
acquire battery monitoring information from the battery,
transmit the battery monitoring information to a controller via wireless communication in response to an instruction from the controller, the controller being configured to execute a predetermined process based on the battery monitoring information, the controller being configured to transmit instructions to monitoring devices via unicast communication and broadcast communication within a communication cycle, the instructions including the instruction transmitted via the unicast communication to each of the monitoring devices about acquisition of the battery monitoring information, and an instruction transmitted via the broadcast communication to the monitoring devices about a timing of acquisition of the battery monitoring information, the monitoring device comprising, and
acquire the battery monitoring information at the timing of acquisition of the instruction transmitted from the controller.

17. The monitoring device according to claim 16, wherein
the processor is further configured to
set a timing of acquisition of the battery monitoring information based on the timing of acquisition transmitted via communication that is later in timing of receiving the instruction among the unicast communication and the broadcast communication in the communication cycle, and
acquire the battery monitoring information at the set timing of acquisition.

18. The monitoring device according to claim 16, wherein
the processor is further configured to acquire the battery monitoring information based on a content received via the unicast communication when a difference between a timing of receiving the battery monitoring information via the unicast communication and a timing of receiving the battery monitoring information via the broadcast communication is greater than or equal to a predetermined threshold.

19. The monitoring device according to claim 17, wherein
the processor is further configured to, after receiving the instruction from the controller about acquisition of the battery monitoring information, transmit the battery monitoring information and an acknowledgement to the controller via the unicast communication in response to the instruction.

20. A non-transitory computer readable medium storing a computer program comprising instructions configured to be executed by a controller configured to acquire battery monitoring information via wireless communication with monitoring devices and execute a predetermined process based on the battery monitoring information, the monitoring devices being configured to acquire the battery monitoring information for monitoring a state of a battery, the instructions, when the program executed by the controller, causing the controller to:
transmit instructions to the monitoring devices via unicast communication and broadcast communication within a communication cycle, the instructions including an instruction transmitted via the unicast communication to each of the monitoring devices about acquisition of the battery monitoring information, and an instruction transmitted via the broadcast communication to the monitoring devices about a timing of acquisition of the battery monitoring information.

21. A method for monitoring a state of a battery, the method comprising:
acquiring battery monitoring information via wireless communication from monitoring devices that acquire the battery monitoring information from the battery;
executing a predetermined process based on the battery monitoring information; and
transmitting instructions to the monitoring devices via unicast communication and broadcast communication within a communication cycle, wherein
the instructions include an instruction transmitted via the unicast communication to each of the monitoring devices about acquisition of the battery monitoring information, and an instruction transmitted via the broadcast communication to the monitoring devices about a timing of acquisition of the battery monitoring information.
